(19) United States
(12) Patent Application Publication
(10) Pub. No.: US 2014/0333287 A1
(43) Pub. Date: Nov. 13, 2014

(54) SYSTEM FOR MEASURING POWER CONSUMPTION OF INTEGRATED CIRCUIT

(71) Applicants: Sunny Gupta, Noida (IN); Kumar Abhishek, Ghaziabad (IN); Manish Kumar, Noida (IN); Himanshu Singhal, New Delhi (IN)

(72) Inventors: Sunny Gupta, Noida (IN); Kumar Abhishek, Ghaziabad (IN); Manish Kumar, Noida (IN); Himanshu Singhal, New Delhi (IN)

(21) Appl. No.: 13/891,214

(22) Filed: May 10, 2013

(51) Int. Cl. G01R 21/00; G01R 21/06

(52) U.S. Cl. CPC G01R 21/006; G01R 21/06
USPC 324/120

(57) ABSTRACT

An integrated circuit includes electronic components, a voltage regulator for generating a control voltage, and a power consumption measurement module. The power consumption measurement module is connected to the voltage regulator and includes an analog-to-digital converter (ADC) for converting the control voltage to multiple digital control voltage samples, an averaging module for averaging the digital control voltage samples, and a current profiling module for receiving the averaged control voltage data and determining an average current from averaged control voltage data. The average current represents power consumption of the integrated circuit.

### BACKGROUND OF THE INVENTION

The present invention relates generally to integrated circuits, and more particularly, to a system for measuring power consumption of an integrated circuit.

An integrated circuit (IC) includes electronic components including processors, memories and interface circuits. The IC further has software programs installed on these electronic components to enable them to perform predefined functions. Examples of software programs include system software programs and application software programs. System software programs control and operate the electronic components, whereas application software programs facilitate a user to perform specific functions/tasks using the IC.

The overall power consumption of the IC depends on the power consumption of the electronic components, which in turn largely depends on the software programs within. The effect of electronic components and system software programs on the power consumption is determined and optimized during IC design and testing phase. However, effect of an application software program on the power consumption can be determined only when the IC executes the application software program when it is in a high power mode. The power consumption of the IC during the high power mode is measured using external current probes, and is monitored using external low voltage detectors.

However, use of external current probes and low voltage detectors increases the overall cost of operation of the IC and cannot determine effect of an application software program on the power consumption, as the current probes cannot identify coding instructions of the application software program that cause excessive power consumption. The current probes further are not effective in optimizing an application software program based on power consumption, when the IC executes the application software program.

Hence, there is a need for a system for measuring power consumption of an IC that does not require external current probes and low voltage detectors, that accurately determines the effect of an application software program on the power consumption, that optimizes the power consumption, and that overcomes the above-mentioned limitations of existing ICs.

### BRIEF DESCRIPTION OF THE DRAWINGS

The following detailed description of the preferred embodiments of the present invention will be better understood when read in conjunction with the appended drawings. The present invention is illustrated by way of example, and not limited by the accompanying figures, in which like references indicate similar elements. It is to be understood that the drawings are not to scale and have been simplified for ease of understanding the invention.

FIG. 1 is a schematic block diagram of an integrated circuit that includes a power consumption measurement module in accordance with an embodiment of the present invention; and

FIG. 2 is a graph illustrating a current profile of the integrated circuit in accordance with an embodiment of the present invention.

### DETAILED DESCRIPTION OF THE INVENTION

The detailed description of the appended drawings is intended as a description of the currently preferred embodiments of the present invention, and is not intended to represent the only form in which the present invention may be practiced. It is to be understood that the same or equivalent functions may be accomplished by different embodiments that are intended to be encompassed within the spirit and scope of the present invention.

In an embodiment of the present invention, an integrated circuit is provided that includes a plurality of electronic components, a voltage regulator connected to the plurality of electronic components, and a power consumption measurement module. The voltage regulator includes a voltage regulator controller, connected to an input power supply for receiving an input supply voltage and generating a control voltage. The voltage regulator further includes a voltage driver that has a gate terminal connected to an output of the voltage regulator controller for receiving the control voltage, a source terminal connected to the input power supply for receiving the input supply voltage, and a drain terminal connected to the plurality of electronic components for providing a regulated voltage thereto. The power consumption measurement module is connected to the gate terminal of the voltage driver, and includes an analog-to-digital converter (ADC),an averaging module connected to the ADC, and a current profiling module connected to the averaging module. The ADC receives and samples the control voltage and generates a plurality of digital control voltage samples. The averaging module receives and averages the plurality of digital control voltage samples to generate an averaged control voltage data. The current profiling module receives the averaged control voltage data and determines an average current, wherein the average current represents power consumption of the integrated circuit.

In another embodiment of the present invention, an integrated circuit is provided that includes a plurality of electronic components, a voltage regulator connected to the plurality of electronic components, and a power consumption measurement module. The voltage regulator includes a voltage regulator controller, connected to an input power supply for receiving an input supply voltage and generating a control voltage. The voltage regulator further includes a voltage driver having a gate terminal connected to an output of the voltage regulator controller for receiving the control voltage, a source terminal connected to the input power supply for receiving the input supply voltage, and a drain terminal connected to the plurality of electronic components for providing a regulated voltage thereto. The power consumption measurement module is connected to the gate terminal of the voltage driver, and includes a unity gain buffer for receiving and buffering the control voltage, an analog-to-digital converter (ADC) connected to the unity gain buffer, an averaging module connected to the ADC, a control register connected to the averaging module, and a current profiling module connected to the control register. The ADC receives and samples the control voltage to generate a plurality of digital control voltage samples. The averaging module receives and averages the plurality of digital control voltage samples to generate an averaged control voltage data. The control register receives and stores the averaged control voltage data. The current profiling module receives the averaged control voltage data, and determines an average current, wherein the average current represents power consumption of the integrated circuit.

In yet another embodiment of the present invention, a power consumption measurement module for an integrated circuit is provided. The integrated circuit includes a plurality of electronic components, and a voltage regulator controller that receives an input supply voltage from an input power supply, and generates a control voltage. A voltage driver has a gate terminal connected to an output of the voltage regulator controller for receiving the control voltage, a source terminal connected to the input power supply for receiving the input supply voltage, and a drain terminal connected to the plurality of electronic components for providing a regulated voltage thereto. The power consumption measurement module includes a unity gain buffer, connected to the gate terminal of the voltage driver, for receiving and buffering the control voltage. An analog-to-digital converter (ADC) is connected to the unity gain buffer for receiving and sampling the control voltage to generate a plurality of digital control voltage samples. An averaging module is connected to the ADC for receiving and averaging the plurality of digital control voltage samples, to generate an averaged control voltage data. A control register is connected to the averaging module for receiving and storing the averaged control voltage data. A current profiling module is connected to the control register for receiving the averaged control voltage data, and determining an average current, wherein the average current represents power consumption of the integrated circuit.

Various embodiments of the present invention provide a system for measuring power consumption of an integrated circuit. The integrated circuit includes a plurality of electronic components, a voltage regulator for generating a control voltage, and a power consumption measurement module connected to the voltage regulator. The power consumption measurement module includes an analog-to-digital converter (ADC) for receiving and converting the control voltage to a plurality of digital control voltage samples, an averaging module for averaging the plurality of digital control voltage samples to generate an averaged control voltage data, and a current profiling module for generating an average current from the averaged control voltage data. The average current represents power consumption of the integrated circuit and may be used to diagnose effect of one or more instructions of an application software program that runs on the electronic components, on the power consumption of the integrated circuit. The average current may further be used to optimize the application software program during execution to minimize the power consumption. The average current may also be used to generate a low voltage detect (LVD) signal when the average current increases beyond a first predetermined threshold current, without using external low voltage detectors and external current probes, which reduces overall costs of the IC operation.

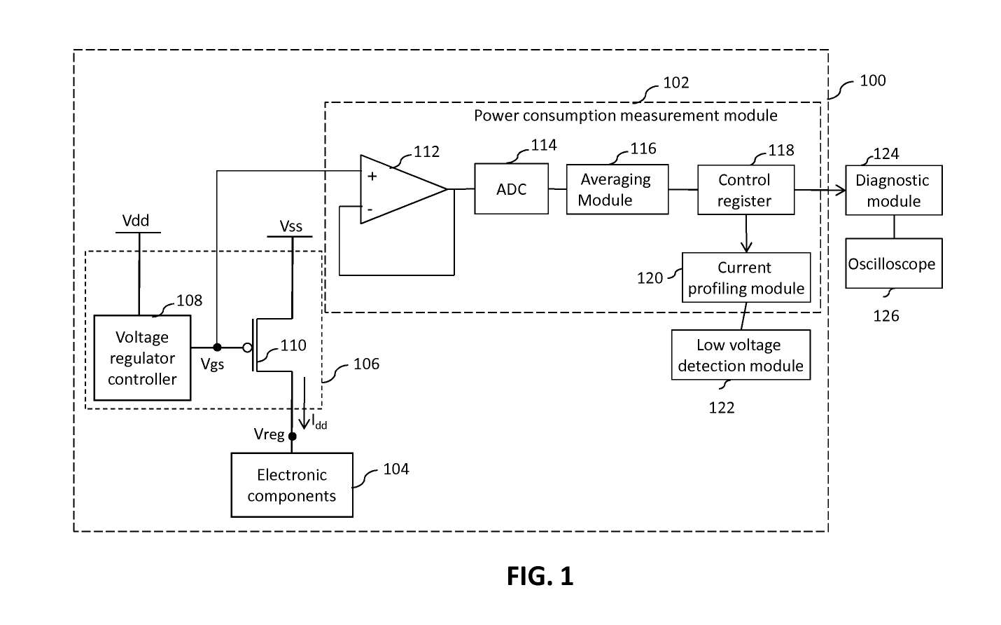

Referring now to FIG. 1, a schematic block diagram of an integrated circuit (IC) 100 including a power consumption measurement module 102 in accordance with an embodiment is shown. Examples of the IC 100 include a microcontroller unit (MCU), a system-on-chip (SoC), or an application specific integrated circuit (ASIC). The IC 100 includes a plurality of electronic components 104, examples of which include digital circuits, analog circuits, or a combination thereof (i.e., mixed signal circuits). A voltage regulator 106 is connected to the plurality of electronic components 104 and provides a regulated voltage V_{reg} to the electronic components 104. The voltage regulator 106 includes a voltage regulator controller 108 and a voltage driver 110. The voltage regulator controller 108 is connected to an input power supply and receives an input supply voltage V_{dd} and generates a control voltage V_{gs}.

The voltage driver 110 may be a p-type metal oxide semiconductor (PMOS) driver that has a gate terminal connected to an output of the voltage regulator controller 108 for receiving the control voltage V_{gs}, a source terminal connected to the input power supply for receiving the input supply voltage V_{dd}, and a drain terminal connected to the electronic components 104 for providing the regulated voltage V_{reg}. The voltage driver 110 operates in a saturation mode to provide a drain current I_{dd} to the electronic components 104 based on the control voltage V_{gs}. At constant regulated voltage V_{reg}, the drain current I_{dd} is proportional to the control voltage V_{gs} and the relationship between the drain current I_{dd} and the control voltage V_{gs} in saturation mode operation of the voltage driver 110 is given by the equation below:

I_{dd}=k(V_{gs}−Vₜ)² (1)
where,
k=a constant,
I_{dd}=the drain current,
V_{gs}=the control voltage, and
Vₜ=threshold voltage of the voltage driver 110.

The power consumption measurement module 102 is connected to the voltage regulator 106 (i.e., to the gate terminal of the voltage driver 110) and includes a unity gain buffer 112, an analog-to-digital converter (ADC) 114, an averaging module 116, a control register 118, and a current profiling module 120.

The unity gain buffer 112 has a first input terminal connected to the gate terminal of the voltage driver 110 and a second input terminal connected to an output terminal thereof. The unity gain buffer 112 receives and buffers the control voltage V_{gs}. The ADC 114 is connected to the output terminal of the unity gain buffer 112 and receives and samples the control voltage V_{gs}. The sampling rate of the ADC 114 may be pre-programmed to generate a plurality of digital control voltage samples.

The averaging module 116 is connected to the ADC 114 and receives and averages the digital control voltage samples and generates an averaged control voltage data. In an embodiment of the present invention, the function of the averaging module 116 may be programmed in to an ASIC by way of software instructions. The control register 118 is connected to the averaging module 116 and receives and stores the averaged control voltage data. In an exemplary embodiment of the present invention, the control register 118 is a first-in first-out (FIFO) register.

The current profiling module 120 is connected to the control register 118 and receives the averaged control voltage data and generates an average current I_{avg}. In an embodiment of the present invention, the function of the current profiling module 120 may be programmed in to an ASIC using software instructions. The average current I_{avg} is approximately equal to the drain current I_{dd} and is estimated by the equation below:

I_{avg}=β(V_{gs}+γ(V_{dd}−3)−Vₜ−δ(T+40))^{α} (2)
Where,
β,γ,δ and α=constants,
V_{gs}=the averaged control voltage data,
V_{dd}=input supply voltage,
Vₜ=threshold voltage of the voltage driver 110, and
T=temperature of the IC 100.

The equation (2) is obtained by adding correction factors for V_{dd} and temperature to the equation (1) for accounting V_{dd} and temperature variations and minimizing a mean squared error between the average current I_{avg} and the drain current I_{dd}.

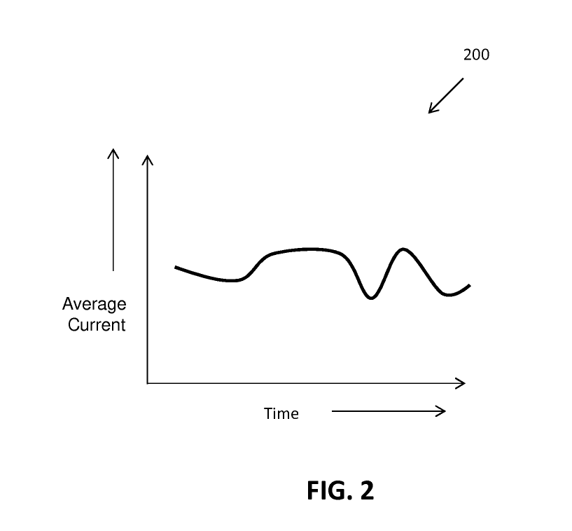

FIG. 2 illustrates graphical current profile 200 of the IC 100. The current profile 200 illustrates current consumption of the IC 100 with respect to time, and is generated by the current profiling module 120 based on the average current I_{avg}. The power consumption of the IC 100 is proportional to the current consumption of the IC 100 and therefore, the current profile 200 represents power consumption of the IC 100 with respect to time.

The IC 100 may further include an internal low voltage detection module 122 that is connected to the current profiling module 120 and generates a low voltage detect (LVD) signal when the average current I_{avg} increases beyond a first predetermined threshold current. The IC 100 may then transition into a reset or interrupt or safe state based on the LVD signal.

In an embodiment of the present invention, an external diagnostic module 124 may be connected to the control register 118 by way of a general purpose input/output (GPIO) interface (not shown) and generates the current profile 200 based on the averaged control voltage data and analyses the power consumption of the IC 100, with respect to one or more instructions of an application software program executed on the IC 100. The diagnostic module 124 accesses the averaged control voltage data from the GPIO interface by way of direct memory access (DMA). The diagnostic module 124 may be a software program that determines the average current I_{avg} based on the averaged control voltage data using the equation (2) and diagnoses effect of one or more instructions of the application software over power consumption of the IC 100.

In various embodiments, the diagnostic module 124 may be connected to an oscilloscope 126 (external to the IC 100) that displays the current profile 200.

In another embodiment of the present invention, the diagnostic module 124 may be used to optimize an application software program during development of the software program, based on the average current I_{avg} of the IC 100. The diagnostic module 124 identifies and modifies instructions of the application software program that cause excessive power consumption during execution. The diagnostic module 124 may set a threshold power consumption for the application software program, and include a safe state mechanism in the application software program in case the IC 100 exceeds the threshold power consumption during execution of the application software program.

While particular embodiments of the present invention have been shown and described, it will be recognized to those skilled in the art that, based upon the teachings herein, further changes and modifications may be made without departing from this invention and its broader aspects, and thus, the appended claims are to encompass within their scope all such changes and modifications as are within the true spirit and scope of this invention.

1. An integrated circuit, comprising:
a plurality of electronic components;
a voltage regulator, connected to the plurality of electronic components, and comprising:
a voltage regulator controller, connected to an input power supply, that receives an input supply voltage and generates a control voltage; and
a voltage driver having a gate terminal connected to an output of the voltage regulator controller for receiving the control voltage, a source terminal connected to the input power supply for receiving the input supply voltage, and a drain terminal connected to the plurality of electronic components for providing a regulated voltage thereto; and
a power consumption measurement module, connected to the gate terminal of the voltage driver, wherein the power consumption measurement module comprises:
an analog-to-digital converter (ADC), that receives and samples the control voltage and generates a plurality of digital control voltage samples;
an averaging module, connected to the ADC, that receives and averages the plurality of digital control voltage samples and generates averaged control voltage data; and
a current profiling module, connected to the averaging module, that receives the averaged control voltage data and determines an average current, wherein the average current represents power consumption of the integrated circuit.

2. The integrated circuit of claim 1, wherein the current profiling module determines the average current based on a predetermined relationship between the averaged control voltage data and a predefined temperature of the integrated circuit.

3. The integrated circuit of claim 1, wherein the power consumption measurement module further comprises a control register, connected between the averaging module and the current profiling module, for receiving and storing the averaged control voltage data.

4. The integrated circuit of claim 1, wherein the control register is configured to be connected to a diagnostic module.

5. The integrated circuit of claim 4, wherein the diagnostic module diagnoses an effect of one or more instructions of an application software program executed by the integrated circuit, on the power consumption of the integrated circuit, based on the average current.

6. The integrated circuit of claim 1, wherein the power consumption measurement module further comprises a unity gain buffer connected between the voltage driver and the ADC for buffering the control voltage.

7. The integrated circuit of claim 1, wherein the voltage driver is a p-type metal oxide semiconductor (PMOS) driver.

8. The integrated circuit of claim 1, further comprising a low voltage detection module, connected to the current profiling module, that generates a low voltage detect (LVD) signal when the average current increases beyond a first predetermined threshold value.

9. The integrated circuit of claim 8, wherein the integrated circuit transitions to a reset state based on the LVD signal.

10. An integrated circuit, comprising:
a plurality of electronic components;
a voltage regulator, connected to the plurality of electronic components, and comprising:
a voltage regulator controller, connected to an input power supply, that receives an input supply voltage and generates a control voltage; and
a voltage driver having a gate terminal connected to an output of the voltage regulator controller for receiving the control voltage, a source terminal connected to the input power supply for receiving the input supply voltage, and a drain terminal connected to the plurality of electronic components for providing a regulated voltage thereto; and
a power consumption measurement module connected to the gate terminal of the voltage driver, wherein the power consumption measurement module comprises:
a unity gain buffer that receives and buffers the control voltage;
an analog-to-digital converter (ADC), connected to the unity gain buffer, that receives and samples the control voltage and generates a plurality of digital control voltage samples;
an averaging module, connected to the ADC, that receives and averages the plurality of digital control voltage samples and generates averaged control voltage data;
a control register, connected to the averaging module, that receives and stores the averaged control voltage data; and
a current profiling module, connected to the control register, that receives the averaged control voltage data, and determines an average current, wherein the average current represents power consumption of the integrated circuit.

11. The integrated circuit of claim 10, wherein the current profiling module determines the average current based on a predetermined relationship between the averaged control voltage data and a predefined temperature of the integrated circuit.

12. The integrated circuit of claim 10, wherein the control register is configured to be connected to a diagnostic module.

13. The integrated circuit of claim 12, wherein the diagnostic module diagnoses an effect of one or more instructions of an application software program executed by the integrated circuit, on the power consumption of the integrated circuit, based on the average current.

14. The integrated circuit of claim 10, wherein the voltage driver is a p-type metal oxide semiconductor (PMOS) driver.

15. The integrated circuit of claim 10, further comprising a low voltage detection module, connected to the current profiling module, that generates a low voltage detect (LVD) signal when the average current increases beyond a first predetermined threshold value.

16. The integrated circuit of claim 15, wherein the LVD signal causes the integrated circuit to transition to a reset state.

17. A power consumption measurement module for an integrated circuit, wherein the integrated circuit comprises a plurality of electronic components, a voltage regulator controller that receives an input supply voltage from an input power supply, and generates a control voltage, and a voltage driver having a gate terminal connected to an output of the voltage regulator controller for receiving the control voltage, a source terminal connected to the input power supply for receiving the input supply voltage, and a drain terminal connected to the plurality of electronic components for providing a regulated voltage thereto, wherein the power consumption measurement module comprises:
a unity gain buffer, connected to the gate terminal of the voltage driver, for receiving and buffering the control voltage; an analog-to-digital converter (ADC), connected to the unity gain buffer, that receives and samples the control voltage and generates a plurality of digital control voltage samples;
an averaging module, connected to the ADC, that receives and averages the plurality of digital control voltage samples and generates averaged control voltage data;
a control register, connected to the averaging module, that receives and stores the averaged control voltage data; and
a current profiling module, connected to the control register, that receives the averaged control voltage data, and determines an average current, wherein the average current represents power consumption of the integrated circuit.

18. The power consumption measurement module of claim 17, wherein the current profiling module determines the average current based on a predetermined relationship between the averaged control voltage data and a predefined temperature of the integrated circuit.

19. The power consumption measurement module of claim 17, wherein the voltage driver is a p-type metal oxide semiconductor (PMOS) driver.

20. The power consumption measurement module of claim 17, wherein the control register is configured to be connected to a diagnostic module that diagnoses an effect of one or more instructions of an application software program executed by the integrated circuit, on the power consumption of the integrated circuit, based on the average current.
